(19) United States
(12) Patent Application Publication
(10) Pub. No.: US 2009/0145478 A1
(43) Pub. Date: Jun. 11, 2009

(54) SURFACE PROTECTIVE SHEET FOR SOLAR CELL AND SOLAR CELL MODULE

(75) Inventor: Naoki TAKAHASHI, Kizugawa-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 12/329,194

(22) Filed: Dec. 5, 2008

(30) Foreign Application Priority Data
Dec. 7, 2007 (JP) 2007-317044
Dec. 3, 2008 (JP) 2008-308792

(51) Int. Cl. H01L 31/00

(52) U.S. Cl. 136/256

(57) ABSTRACT

The present invention is a surface protective sheet for a solar cell including a polyethylene naphthalate film and an inorganic oxide film formed on one surface of the polyethylene naphthalate film, in which the absorbance of light having a wavelength from 350 nm to 400 nm is from 1% to 20% or the absorbance of light having a wavelength of 380 nm is from 1% to 20%, and a solar cell module using the same.

This nonprovisional application is based on Japanese Patent Application No. 2007-317044 filed on Dec. 7, 2007 and No. 2008-308792 filed on Dec. 3, 2008 with the Japan Patent Office, the entire contents of which are hereby incorporated by reference.

### BACKGROUND OF THE INVENTION

1. Field of the Invention

The present invention relates to a surface protective sheet for a solar cell and a solar cell module, and especially relates to a surface protective sheet for a solar cell capable of suppressing a decrease of output of the solar cell module during a long period of use, and a solar cell module using the same.

2. Description of the Background Art

In recent years, from the viewpoint of effective use of natural resources and the prevention of environmental pollution, a solar cell module that converts sunlight directly into electric energy has been attracted attention, and development thereof has been made.

As shown in a schematic cross-sectional view in FIG. 15, the solar cell module generally has a constitution where silicon solar cells 104 are sealed in an ethylenevinylacetate (EVA) resin 103 that are connected in series by an interconnect 105 between a glass substrate 101 as a light receiving side transparent protective member and a rear surface side protective member 102.

Here, the light receiving side transparent protective member provided on the light receiving side of the solar cell module is firstly required to have excellent durability against ultraviolet rays of the sunlight. In addition, having excellent moisture proof properties becomes an extremely important requirement to suppress the generation of rust in conducting wires or electrodes inside the solar cell module due to moisture or permeation of water. For this reason, a glass plate has been conventionally used as the light receiving side transparent protective member provided on the light receiving side of the solar cell module.

However, though a glass plate has excellent in light resistance properties and moisture proof properties, it has a problem that the weight is large and has a disadvantage of being weak and easily broken.

Then, for example, a technique is disclosed in Japanese Patent Laying-Open No. 2000-174296 (Patent Document 1) of using a surface protective sheet for a solar cell as the light receiving side transparent protective member provided on the light receiving side of the solar cell module, and the constitution of the surface protective sheet for a solar cell in Patent Document 1 is shown in a schematic cross-sectional view in FIG. 16.

Here, a surface protective sheet for a solar cell 201 in Patent Document 1 has a constitution where a transparent highly light resistant film 202, an adhesive sheet 203, and a transparent highly moisture proof film 204 are arranged from the light receiving surface side of the solar cell module in this order. Further, Patent Document 1 describes that a film composed of a resin composition is used as transparent highly light resistant film 202 where, a benzophenone-based ultraviolet ray absorbing material such as 2-hydroxy-4-octoxybenzephenone and 2-hydroxy-methoxy-5-sulfobenzophenone, a benzotriazole-based ultraviolet ray absorbing material such as 2-(2′-hydroxy-5-methylphenyl)benzotriazole, and a hindered amine-based ultraviolet ray absorbing material such as phenylsalicylate and p-t-butyl phenylsalicylate are used as the ultraviolet ray absorber, and the ultraviolet ray absorber is normally kneaded into a base material resin composed of polyethylene naphthalate where the ultraviolet ray absorber is compounded at about 1 to 20% by weight in a normal case.

### SUMMARY OF THE INVENTION

However, when using polyethylenenaphtalate where the ultraviolet ray absorber is kneaded into transparent highly light resistant film 202 as in surface protective sheet for a solar cell 201 in Patent Document 1, the ultraviolet ray can be prevented from penetrating transparent highly moisture proof film 204 that becomes an underlayer of transparent highly light resistant film 202. However, it was found that the transmittance of the sunlight through transparent highly light resistant film 202 gradually decreases since transparent highly light resistant film 202 absorbs the ultraviolet rays of the sunlight.

Therefore, when producing a solar cell module using surface protective sheet for a solar cell 201 described in Patent Document 1, because the transmittance of the sunlight through transparent highly light resistant film 202 gradually decreases due to the ultraviolet rays of the sunlight, there is a problem that output of the solar cell module decreases simultaneously.

In view of the above situation, an object of the present invention is to provide a surface protective sheet for a solar cell capable of suppressing a decrease of output of a solar cell module during a long period of use, and a solar cell module using the same.

The present invention is a surface protective sheet for a solar cell including a polyethylene naphthalate film and an inorganic oxide film formed on one surface of the polyethylene naphthalate film, wherein the absorbance of light having a wavelength from 350 nm to 400 nm is from 1% to 20%.

Further, the present invention is a surface protective sheet for a solar cell including a polyethylene naphthalate film and an inorganic oxide film formed on one surface of the polyethylene naphthalate film, wherein the absorbance of light having a wavelength of 380 nm is from 1% to 20%.

Here, in the surface protective sheet for a solar cell in the present invention, the inorganic oxide film is preferably a laminated body of a silicon oxide film and a titanium oxide film or a laminated body of a silicon oxide film and a tantalum oxide film.

Further, in the surface protective sheet for a solar cell in the present invention, a silicon oxide film is preferably positioned on the outermost surface of the inorganic oxide film.

Further, in the surface protective sheet for a solar cell in the present invention, an organic compound film is formed between the polyethylene naphthalate film and the inorganic oxide film, and the organic compound film is preferably formed by curing a radiation curable resin.

Further, in the surface protective sheet for a solar cell in the present invention, a silicon oxide film is preferably formed on the surface of the polyethylene naphthalate film opposite to the side where the inorganic oxide film is provided.

Furthermore, the present invention is a solar cell module in which the surface protective sheet for a solar cell and a solar cell are adhered to each other with a silicone resin interposed therebetween, while the surface of any of the surface protective sheet for a solar cell opposite to the side where the inorganic oxide film is provided is a solar cell side.

Further, the present invention is a surface protective sheet for a solar cell including a polyamide-imide film and an inorganic oxide film formed on one surface of the polyamide-imide film, wherein the absorbance of light having a wavelength of from 300 nm to 350 nm is from 1% to 20%.

Further, the present invention is a surface protective sheet for a solar cell including a polyamide-imide film and an inorganic oxide film formed on one surface of the polyamide-imide film, wherein the absorbance of light having a wavelength of 325 nm is from 1% to 20%.

According to the present invention, it can provide a surface protective sheet for a solar cell capable of suppressing a decrease of output of a solar cell module during a long period of use, and a solar cell module using the same.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of one example of the surface protective sheet for a solar cell of the present invention.

FIG. 2 is a schematic cross-sectional view of another example of the surface protective sheet for a solar cell of the present invention.

FIG. 3 is a schematic cross-sectional view illustrating one pan of a step of one example of a method for producing a solar cell module using the surface protective sheet for a solar cell of the present invention.

FIG. 4 is a schematic cross-sectional view illustrating another part of a step of one example of a method for producing a solar cell module using the surface protective sheet for a solar cell of the present invention.

FIG. 5 is a schematic cross-sectional view illustrating another part of a step of one example of a method for producing a solar cell module using the surface protective sheet for a solar cell of the present invention.

FIGS. 6A and 6B are views showing the relationship of the light wavelength and transmittance of the polyethylene naphthalate film before and after irradiating the polyethylene naphthalate film with an ultraviolet ray equivalent to 25 days.

FIGS. 7A and 7B are views showing the relationship of the light wavelength and transmittance of the polyethylene naphthalate film.

FIGS. 8A and 8B are views showing the relationship of the light wavelength and reflectance of the polyethylene naphthalate film.

FIGS. 9A and 9B are views showing the result of calculating the absorbance of the polyethylene naphthalate film based on the result of FIGS. 7A, 7B, 8A and 8B.

FIGS. 10A and 10B are views showing the relationship of the reflectance and light wavelength of each of the surface protective sheets for a solar cell in conditions 1 to 6.

FIGS. 11A and 11B are views showing the relationship of the transmittance and light wavelength of each of the surface protective sheets for a solar cell in conditions 1 to 6.

FIGS. 12A and 12B are views showing the relationship of the absorbance and light wavelength of each of the surface protective sheet for a solar cell in conditions 1 to 6 calculated from FIGS. 10A, 10B, 11A and 11B.

FIG. 13A is a schematic planar view of one example of the solar cell module, and FIG. 13B is a schematic cross-sectional view of the solar cell module shown in FIG. 13A.

FIG. 14 is a view showing the relationship of the rate of output of the solar cell module when irradiating pseudo sunlight equivalent to 3000 days onto the solar cell module produced using each of the surface protective sheets for a solar cell in conditions 1 to 6 and absorbance of light having a wavelength of 380 nm through the surface protective sheet for a solar cell.

FIG. 15 is a schematic cross-sectional view of one example of a conventional solar cell module.

FIG. 16 is a schematic cross-sectional view showing a constitution of the conventional surface protective sheet for a solar cell described in Patent Document 1.

FIGS. 17A and 177B are views showing the relationship of the light wavelength and transmittance of the polyamide-imide film.

FIGS. 18A and 18B are views showing the relationship of the light wavelength and reflectance of the polyamide-imide film.

FIGS. 19A and 19B are views showing the result of calculating the absorbance of the polyamide-imide film based on the result of FIGS. 17A, 17B, 18A and 18B.

FIGS. 20A and 20B are views showing the relationship of the reflectance and light wavelength of the surface protective sheets for a solar cell in condition 13.

FIGS. 21A and 21B are views showing the relationship of the transmittance and light wavelength of the surface protective sheets for a solar cell in condition 13.

FIGS. 22A and 22B are views showing the relationship of the absorbance and light wavelength of the surface protective sheet for a solar cell in condition 13 calculated from FIGS. 20A, 20B, 21A and 21B.

FIG. 23A is a schematic planar view of one example of the solar cell module, and FIG. 23B is a schematic cross-sectional view of the solar cell module shown in FIG. 23A.

FIG. 24 is a view showing the relationship of the rate of output of the solar cell module when irradiating pseudo sunlight equivalent to 3000 days onto the solar cell module produced using each of the surface protective sheets for a solar cell in conditions 11 to 13 and absorbance of light having a wavelength of 325 nm through the surface protective sheet for a solar cell.

### DESCRIPTION OF THE PREFERRED EMBODIMENTS

The embodiment of the present invention is described below. Moreover, the same reference numerals in the drawings in the present invention represent the same part or equivalent part.

FIG. 1 shows a schematic cross-sectional view of one example of the surface protective sheet for a solar cell of the present invention. Here, a surface protective sheet for a solar cell 1 has a polyethylene naphthalate film 2 and an inorganic oxide film 3 formed on one surface of polyethylene naphthalate 2. Then, the absorbance of light having a wavelength form 350 nm to 400 nm over the entire of surface protective sheet for a solar cell 1 is from 1% to 20%, and the absorbance of light particularly having a wavelength of 380 nm is from 1% to 20%.

The present inventors found that a decrease of output of a solar cell module can be suppressed in the case where the a solar cell module is produced by providing surface protective sheet for a solar cell 1 having the above constitution on the light receiving side of the solar cell, even when the solar cell module is exposed to the ultraviolet rays of sunlight for a long period of time, and came to complete the present invention.

Here, the conventionally known polyethylene naphthalate film can be used as polyethyelnenaphtalate film 2, and a Teonex Q65FA film manufactured by Tijin DuPont Films Japan Limited, etc. can be specifically used.

Further, the thickness of polyethylene naphthalate film 2 is preferably from 25 μm to 100 μm, and more preferably from 50 μm to 75 μm. In the case where the thickness of polyethylene naphthalate film 2 is from 25 μm to 100 μm, and particularly where from 50 μm to 75 μm, the deterioration rate of the maximum output of the solar cell module due to radiation equivalent to 5 years in a satellite orbit of the earth can be suppressed to about 5%, and the increase of the mass of the solar cell module due to a increase in thickness of polyethylene naphthalate film 2 tends to be minimized.

Further, an example of inorganic oxide film 3 that can be used is oxide films of at least one layer having high reflectance against the ultraviolet rays of sunlight, and among them, a laminated body of a silicon oxide film and a titanium oxide film or a laminated body of a silicon oxide film and a tantalum oxide film is preferably used. In the case where the laminated body of a silicon oxide film and a titanium oxide film or the laminated body of a silicon oxide film and a tantalum oxide film is used as inorganic oxide film 3, because the decrease of the transmittance of sunlight through surface protective sheet for a solar cell 1 greatly tends to be suppressed, a decrease of output of the solar cell module greatly tends to be suppressed even when the solar cell module is exposed to the ultraviolet rays of sunlight for a long time.

Moreover, the laminated body of a silicon oxide film and a titanium oxide film may have a constitution where the silicon oxide film and the titanium oxide film are alternatively laminated, and there may be at least one layer of each of the silicon oxide film and the titanium oxide film that constitutes the laminated body.

Further, the laminated body of a silicon oxide film and a tantalum oxide film may also have a constitution where the silicon oxide film and the tantalum oxide film are alternatively laminated, and there may be at least one layer of each of the silicon oxide film and the tantalum oxide film that constitutes the laminated body.

Further, a silicon oxide film is preferably positioned on the most outside surface of inorganic oxide film 3 (that is, the surface of inorganic oxide film 3 that is away from polyethylene naphthalate film 2; referred to as “the outermost surface” below). Because deterioration of surface protective sheet for a solar cell 1 caused by irradiation of atomic oxygen can be suppressed in this case, the decrease of the transmittance of sunlight of surface protective sheet for a solar cell 1 greatly tends to be suppressed.

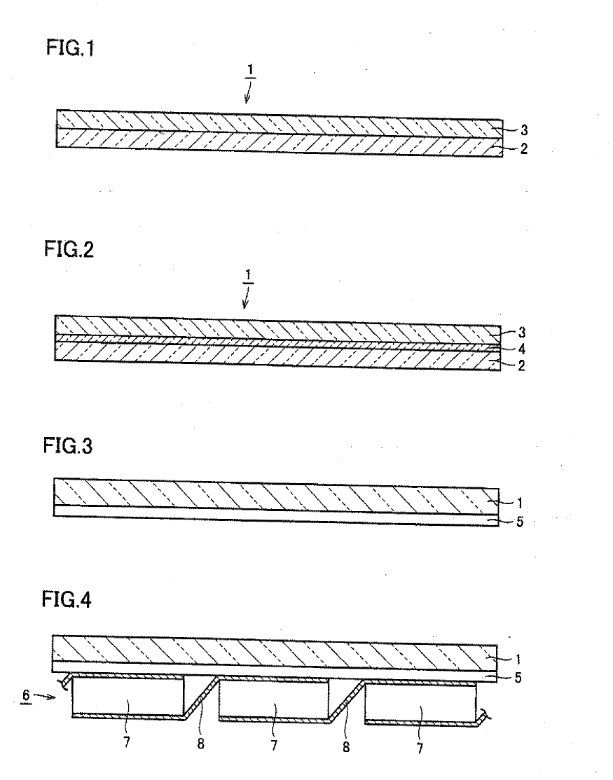

A schematic cross-sectional view of another example of the surface protective sheet for a solar cell of the present invention is shown in FIG. 2. Here, in surface protective sheet for a solar cell 1, an organic compound film 4 is provided between polyethylene naphthalate film 2 and inorganic oxide film 3 formed on one surface of polyethylene naphthalate film 2. Also in surface protective sheet for a solar cell 1 shown in FIG. 2, the absorbance of light having a wavelength form 350 nm to 400 nm over the entire of surface protective sheet for a solar cell 1 is from 1% to 20%, and the absorbance of light particularly having a wavelength of 380 nm is from 1% to 20%.

As described above, by providing organic compound film 4 between polyethylene naphthalate film 2 and inorganic oxide film 3, the generation of cracks of inorganic oxide film 3 caused by a difference in thermal expansion coefficients between polyethylene naphthalate film 2 and inorganic oxide film 3 and the generation of peeling of inorganic oxide film 3 from polyethylene naphthalate film 2 tends to be suppressed effectively even when the temperature of surface protective sheet for a solar cell 1 increases due to reasons such as being exposed to sunlight for a long period of time.

Here, for example, those that are cured by irradiating a radiation curable resin with radiation, etc. can be used as organic compound film 4. Moreover, radiation means for example, infrared rays, visible light rays, ultraviolet rays, and ionizing radiation such as X rays electron beams, α rays, β rays, and γ rays, and light such as ultraviolet rays can be normally used.

Further, a multifunctional acrylate based radiation curable resin such as a polyolacrylate based resin, a polyesteracrylate based resin, an urethaneacrylate based resin, and an epoxyacrylate based resin can be used as the radiation curable resin. Moreover, a photopolymerization initiator and/or a photosensitizer that are conventionally known may be added into the radiation curable resin if necessary. Further, at least one type of conventionally known additives may be added into the radiation curable resin such as an antioxidant, an ultraviolet ray absorber, a photo stabilizer, a silane coupling agent, a coating surface modifier, a thermal polymerization inhibiter, a leveling agent, a surfactant, a coloring agent, a storage stabilizer, a plasticizer, a lubricant, a releasing agent, a solvent, a filler, an anti-aging agent, and a wetness modifier, for example, if necessary.

A conventionally known polyolacrylate based resin can be used, and examples thereof include resins of trimethylolpropanetriacrylate, ditrimethylolpropanetetraacrylate, pentaerythritoltriacrylate, pentaerythritoltetraacrylate, dipentaerthritolhexaacrylate, alkyl-modified dipentaerythritholpentaacrylate, etc. A conventionally known photoreaction initiator and/or photosensitizer can be added into these resins.

A conventionally known polyesteracrylate based resin can be used, and a resin obtained by reacting an acrylate based monomer having a hydroxy group such as 2-hydroxyethylacrylate, 2-hydroxyethylmethacrylate, and 2-hydroxypropylacrylate with polyester polyol can be used, for example.

A conventionally known urethaneacrylate based resin can be used, and a resin obtained by furthermore reacting an acrylate based monomer having a hydroxy group such as 2-hydroxyethylacrylate, 2-hydroxyethylmethacrylate, and 2-hydroxypropylacrylate with a product obtained by generally reacting an isocyanate monomer or prepolymer with polyesterpolyol can be used, for example.

A conventionally known epoxyacrylate based resin can be used, and a resin obtained by making epoxyacrylate as an oligomer, adding a reactive diluent and a photo reaction initiator into this oligomer to be reacted, etc. can be used, for example.

Further, the thickness of organic compound film 4 is preferably from 1 μm to 10 μm, and more preferably from 3 μm to 6 μm. In the case where the thickness of organic compound film 4 is made to be from 1 μm to 10 μm, and especially from 3 μm to 6 μm, the generation of cracks of inorganic oxide film 3 caused by a difference in thermal expansion coefficients between polyethylene naphthalate film 2 and inorganic oxide film 3 can be suppressed effectively, and a decrease of the transmittance of surface protective sheer for a solar cell 1 tends to be suppressed.

Surface protective sheet for a solar cell 1 having the above constitution can be manufactured as follows for example.

First, polyethylene naphthalate film 2 is prepared by cutting out a polyethylene naphthalate film in the market to an appropriate size. Next, a polyolacrylate based resin is applied onto one surface of polyethylene naphthalate film 2 to be a thickness of about 5 μm with an applicator, the applied polyolacrylate based resin is dried with a hot blown air at a temperature of 75° C. for 10 minutes, and then the polyolacrylate based resin is cured by performing an ultraviolet ray irradiation using a high pressure mercury lamp 8 W/cm from a height of 20 cm at a conveyor speed of 5 m/min. According to the above description, organic compound film 4 that is made by curing the polyolacrylate based resin on the surface of polyethylene naphthalate film 2 is formed. Moreover, a multi-functional acrylate based radiation curable resin such as a polyesteracrylate based resin, an urethaneacrylate based resin, and an epoxyacrylate based resin can be also used instead of the polyolacrylate based resin. Moreover, in case of producing surface protective sheet for a solar cell 1 shown in FIG. 1, it is needless to say that there is no necessity of forming organic compound film 4.

Next, inorganic oxide film 3 is formed on one surface of polyethylene naphthalate film 2. Further, in case of forming organic compound film 4 that is made by curing the above multi-functional acrylate based radiation curable resin on the surface of polyethylene naphthalate film 2, inorganic oxide film 3 is formed on the surface of organic compound film 4. Inorganic oxide film 3 is preferably formed by a laminated body of a silicon oxide film and titanium oxide film or a laminated body of a silicon oxide film and a tantalum oxide film in accordance with a vapor deposition method, a sputter method, etc. for example. Because the size of the wavelength range of reflecting light and the center of the wavelength of reflecting light (the wavelength of light at which the reflectance becomes the highest) can be generally changed by appropriately adjusting the thickness etc. of each layer of the above laminated bodies, the absorbance of light having a wavelength from 350 nm to 400 nm over the entire of surface protective sheet for a solar cell 1 can be adjusted to 1% to 20%, and the absorbance of light particularly having a wavelength of 380 nm can be adjusted to 1% to 20%.

According to the above description, surface protective sheet for a solar cell 1 shown in FIG. 1 or FIG. 2 can be manufactured. Moreover, the side where inorganic oxide film 3 is formed can be used as the light receiving surface side of surface protective sheet for a solar cell 1.

Here, a silicon oxide film is preferably formed on the surface of surface protective sheet for a solar cell 1 shown in FIG. 1 or FIG. 2 that becomes the rear surface side (opposite to the light receiving surface side) of polyethylene naphthalate film 2. In this case, the reflection of sunlight at the rear surface side of polyethylene naphthalate film 2 can be suppressed, and at the same time adhesiveness with the silicon resin described later tends to improve.

Referring to the schematic cross-sectional views in FIG. 3 to FIG. 5, one example of a method for producing a solar cell module using surface protective sheet for a solar cell 1 produced as described above is described below.

First, surface protective sheet for a solar cell 1 produced as described above is prepared, and a silicone resin 5 is applied onto the surface of the rear surface side of surface protective sheet for a solar cell 1. Here, a roller, etc. is made to absorb the silicone resin 5, and the silicone resin 5 is preferably applied onto the surface of the rear surface side of surface protective sheet for a solar cell 1 using the roller, for example. In this case, silicone resin 5 tends to be applied in almost uniform thickness and thinly. Moreover, in the present invention, silicone resin 5 may be applied in accordance with a method other than the method using a roller. Further, a conventionally known silicone resin can be used as silicone resin 5, and DC93-500 manufactured by Dow Corning Corporation, SYLGARD184 manufactured by the same Dow Corning Corporation, etc. can be used for example.

Next, as shown in FIG. 4, the surface of surface protective sheet for a solar cell 1 where silicone resin 5 is applied and the light receiving surface of a solar cell string 6 are pasted together. Here, solar cell string 6 has a constitution where a plurality of solar cells 7 are connected by an interconnect 8.

Here, the pasting of surface protective sheet for a solar cell 1 and solar cell string 6 can be performed by placing surface protective sheet for a solar cell 1 coated with silicone resin 5 in a vacuum chamber with a condition that solar cell string 6 is placed on the surface coated with silicone resin 5 and forming a vacuum in the vacuum chamber to remove air bubbles between silicone resin 5 and solar cell string 6.

Further, the air bubbles between silicone resin 5 and solar cell string 6 can be removed the same as described above by performing the pasting of solar cell string 6 and surface protective sheet for a solar cell 1 coated with silicone resin 5 itself in the vacuum chamber.

Next, surface protective sheet for a solar cell 1 is adhered to solar cell string 6 by curing silicone resin 5 by heating. Here, silicone resin 5 may be heated using an oven or may be heated using a heater. Further, each of the heating temperature and the heating time of silicone resin 5 can be appropriately set. However, in case of using DC93-500 manufactured by Dow Corning Corporation or SYLGARD184 manufactured by Dow Corning Corporation as silicone resin 5, the heating temperature is set to be about 100° C., and the heating time is set to be about 1 hour.

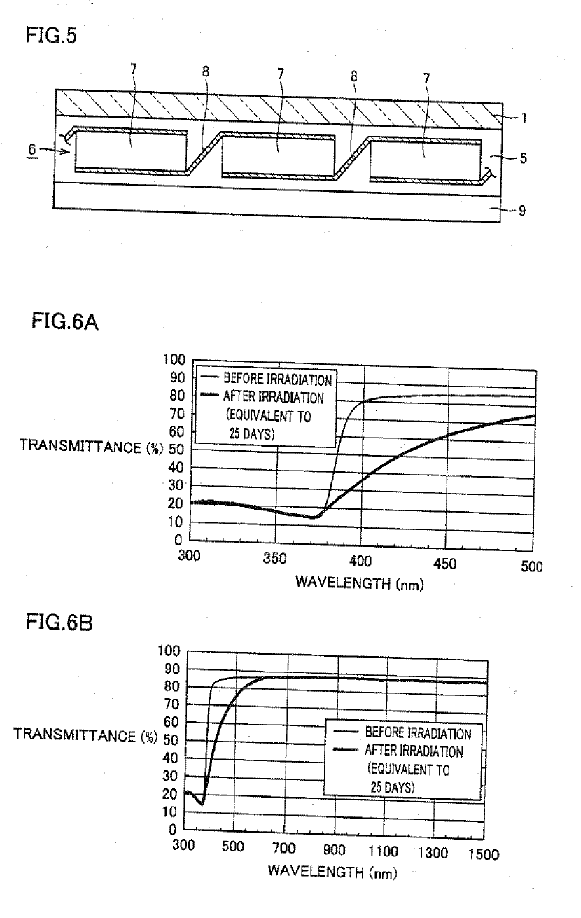

Next, as shown in FIG. 5, a rear surface film 9 is adhered onto the rear surface side of solar cell string 6 with silicone resin 5 interposed therebetween in accordance with the same procedure as described above. Here, the same material as the light receiving surface side of surface protective sheet for a solar cell 1 can be used as rear surface film 9.

According to the above steps, a solar cell module using surface protective sheet for a solar cell 1 is produced.

Moreover, in the above description, a conventionally known compound semiconductor solar cell can be used, for example, as solar cell 7 constituting solar cell module 6, and this compound semiconductor solar cell can be produced as follows. Moreover, in the present invention, solar cell 7 is not limited to a compound semiconductor solar cell, and needless to say, it may be other solar cells such as a silicon solar cell.

First, a plurality of different kinds of compound semiconductor layers are epitaxially grown on the surface of a semiconductor substrate composed of Si, Ge, GaAs, etc. Here, a compound semiconductor layer can be epitaxially grown sequentially so as to have a constitution containing a solar cell layer containing a pn junction and a contact layer to connect a second electrode for example on the surface of the semiconductor substrate.

Next, a mask is formed only on the necessary part of the surface of the compound semiconductor layer in accordance with a photolithography method, and then the part where the mask is not formed is etched. Thereafter, the mask is removed.

Subsequently, a first electrode is formed on the contact layer constituting the light receiving surface of the solar cell layer in accordance with a normal photolithography method, a vapor deposition method, a lift-off method, a sinter method, etc. for example. The first electrode can be constituted from a conductive material such as silver (Ag). Further, the shape of the first electrode may be a comb shape for example. However, all of the electrode shapes can be adopted that can function as solar cell 7 other than a comb shape.

Next, the semiconductor substrate is divided into a plurality of sections so as to be a prescribed shape, and then the second electrode is formed on the rear surface of the semiconductor substrate in accordance with a normal photolithography method, a vapor deposition method, a lift-off method, a sinter method, etc. for example. Here, the second electrode can be constituted from a conductive material such as silver (Ag). All of the electrode shapes that can function as solar cell 7 can be adopted as the shape of the second electrode.

According to the above description, solar cell 7 constituting solar cell module 6 can be produced. Here, cutting out of solar cell 7 can be performed by creating a cut in one unit of necessary part in the periphery of solar cell 7 in accordance with a normal dicing method or a scribe method, and cutting out solar cell 7 in accordance with a normal expand method or a break method.

Then, solar cell string 6 is produced by electrically connecting the first electrode formed on the light receiving surface of one solar cell 7 and the second electrode formed on the rear surface of another solar cell 7 thus produced with interconnect 8 interposed therebetween. Here, interconnect 8 is connected to each of the first electrode and the second electrode by welding in accordance with a normal spot welding method for example. Interconnect 8 is composed of a conductive material such as silver (Ag) for example, and the shape of interconnect 9 is preferably a shape that can be pulled out outwardly from the periphery of solar cell 7.

Then, solar cell strings 6 are connected in parallel to each other at each end of solar cell string 6 by welding a bus bar in accordance with a normal spot welding method.

Because polyethylene naphthalate film 2 and inorganic oxide film 3 having a function of reflecting the ultraviolet ray on one side of polyethylene naphthalate film 2 are formed on surface protective sheet for a solar cell 1 of the present invention and the absorbance of light having a wavelength from 350 nm to 400 nm in surface protective sheet for a solar cell 1 is from 1% to 20%, and the absorbance of light particularly having a wavelength of 380 nm is from 1% to 20%, a decrease of the transmittance of sunlight through surface protective sheet for a solar cell 1 can be suppressed. Therefore, a decrease of output of the solar cell module can be suppressed in case of using a solar cell module produced using surface protective sheet for a solar cell 1 for a long period of time. Therefore, in the solar cell module produced using surface protective sheet for a solar cell 1 of the present invention, it becomes difficult that the amount of power generation deteriorates even when exposed to ultraviolet rays for a long period of time, and it can be a highly durable solar cell module.

Further, in case of using a laminated body of a silicon oxide film and a titanium oxide film or a laminated body of a silicon oxide film and a tantalum oxide film as inorganic oxide film 3, a decrease of the transmittance of sunlight through surface protective sheet for a solar cell 1 tends to be greatly suppressed. Therefore, a decrease of output of the solar cell module tends to be greatly suppressed even when the solar cell module is exposed to the ultraviolet rays of sunlight for a long period of time.

Further, the deterioration of surface protective sheet for a solar cell 1 caused by the irradiation of atomic oxygen can be suppressed by positioning the silicon oxide film on the outermost surface of inorganic oxide film 3. Therefore, a decrease of transmittance of sunlight through surface protective sheet for a solar cell 1 can be suppressed, and a decrease of output of the solar cell module tends to be greatly suppressed.

Further, by providing organic compound film 4 between polyethylene naphthalate film 2 and inorganic oxide film 3, a stress generated due to a difference in thermal expansion coefficients between polyethylene naphthalate film 2 and inorganic oxide film 3 can be relaxed by organic compound film 4 even in the case where the temperature of surface protective sheet for a solar cell 1 is increased because of exposure to sunlight for a long period of time. Therefore, the generation of cracks of inorganic oxide film 3 and the generation of peeling of inorganic oxide film 3 tends to be suppressed effectively. Therefore, the solar cell module produced using surface protective sheet for a solar cell 1 has high durability even in case of being exposed to a severe environment where there is a large temperature difference, and a decrease of output tends to be suppressed greatly.

Further, in case of forming a silicon oxide film on the surface of surface protective sheet for a solar cell 1 of the present invention that becomes the rear surface side (the opposite side from the light receiving surface side) of polyethylene naphthalate film 2, the reflection of sunlight in the rear surface side of polyethylene naphthalate film 2 can be suppressed, and at the same time, adhesiveness with silicone resin 5 tends to be improved. Because soaking of moisture into the solar cell module can be suppressed by improving this adhesiveness, the solar cell module can be made to have high durability even in case of being exposed to a high moisture environment, and a decrease of output tends to be suppressed greatly.

### EXAMPLE

The relationship is shown in FIGS. 6A and 6b of the light wavelength and transmittance of the polyethylene naphthalate film before and after radiating the polyethylene naphthalate film with ultraviolet rays equivalent to 25 days. Here, the irradiation of the ultraviolet ray was performed by condensing light from a halogen lamp having a spectrum that is quasi imitated spectrum of 200 times that of sunlight.

As shown in FIGS. 6A and 6B, the transmittance (%) of light having a wavelength from 380 to 600 nm largely decreased by irradiating the polyethylene naphthalate film with the ultraviolet ray. This is considered because the polyethylene naphthalate film turned yellow due to the irradiation of the ultraviolet ray. Therefore, in case of using only the polyethylene naphthalate film as the surface protective sheet for a solar cell, it is considered that the light transmittance of the polyethylene naphthalate film decreases in accordance with using the solar cell module for a long period of time, and output of the solar cell module decreases.

Actually, a solar cell was produced using each of the polyethylene naphthalate film before and after the irradiation of ultraviolet rays equivalent to 25 days as the surface protective sheet for a solar cell, and a change of output of the solar cell before and after the irradiation of the ultraviolet ray was confirmed. As a result, the output of the solar cell after the irradiation decreased about 22% as compared with that before the irradiation of the ultraviolet ray.

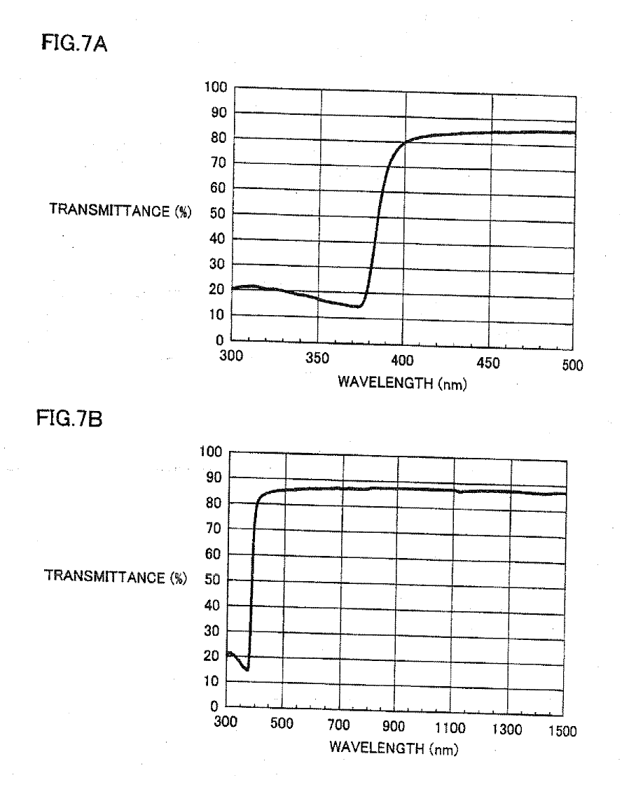

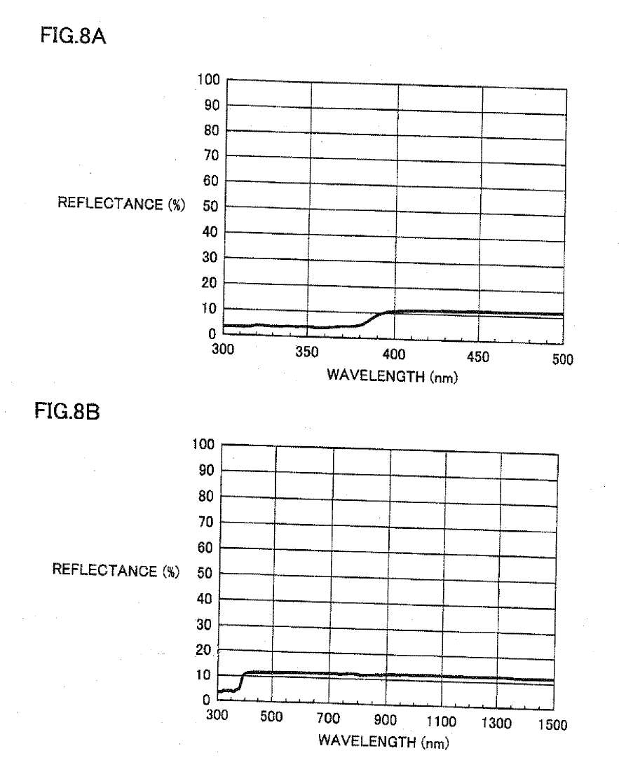

In order to clarify the mechanism of the polyethylene naphthalate film turning yellow, the light transmittance and the reflectance of the polyethylene naphthalate film were measured first. Here, an absolute reflectance measurement apparatus ARN-475 type manufactured by JASCO Corporation was used in the measurements of the transmittance and the reflectance of the polyethylene naphthalate film. The light wavelength used in the measurement of the transmittance and the reflectance of the polyethylene naphthalate film was made to be 300 nm to 1500 nm. The relationship of the light wavelength and transmittance of the polyethylene naphthalate film is shown in FIGS. 7A and 7B, and the relationship of the light wavelength and reflectance of the polyethylene naphthalate film is shown in FIGS. 8A and 8B.

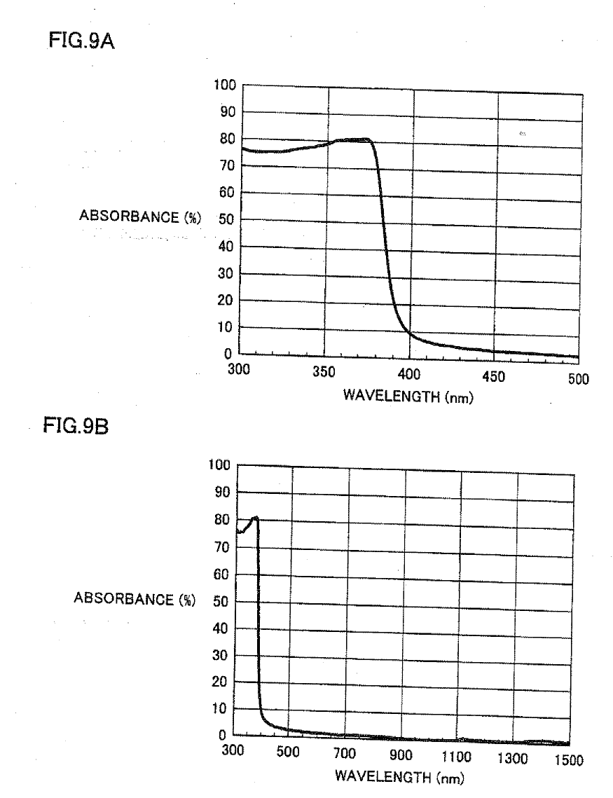

Based on the result of FIGS. 7A, 7B, 8A and 8B, the result of calculating the absorbance of the polyethylene naphthalate film is shown in FIGS. 9A and 9B. Here, the absorbance is defined by the following formula (I).

Absorbance (%)=100(%)−Transmittance (%)−Reflectance (%) (1)

As shown in FIGS. 9A and 9B, it was found that the absorbance of the polyethylene naphthalate film becomes the highest around wavelength 380 nm.

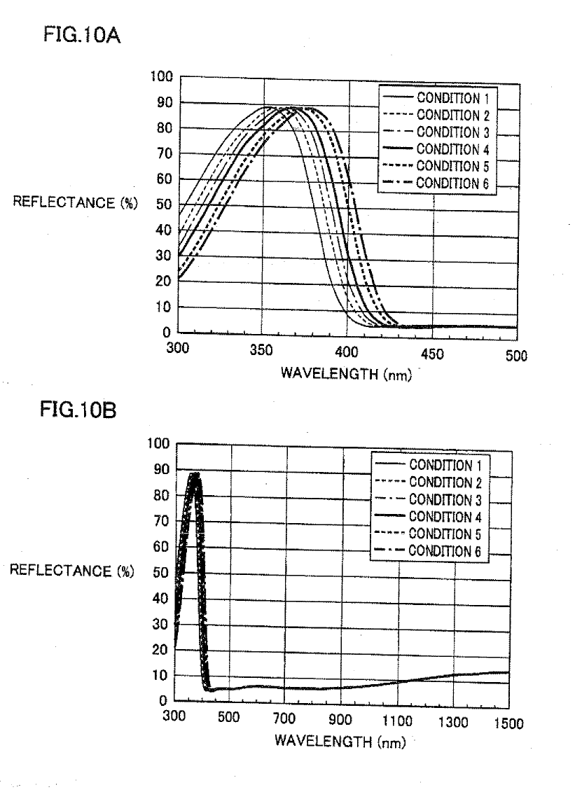

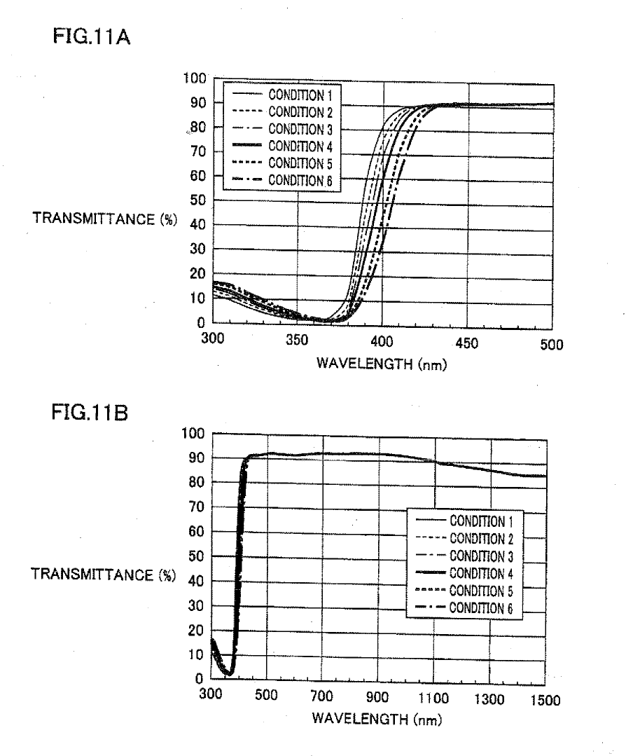

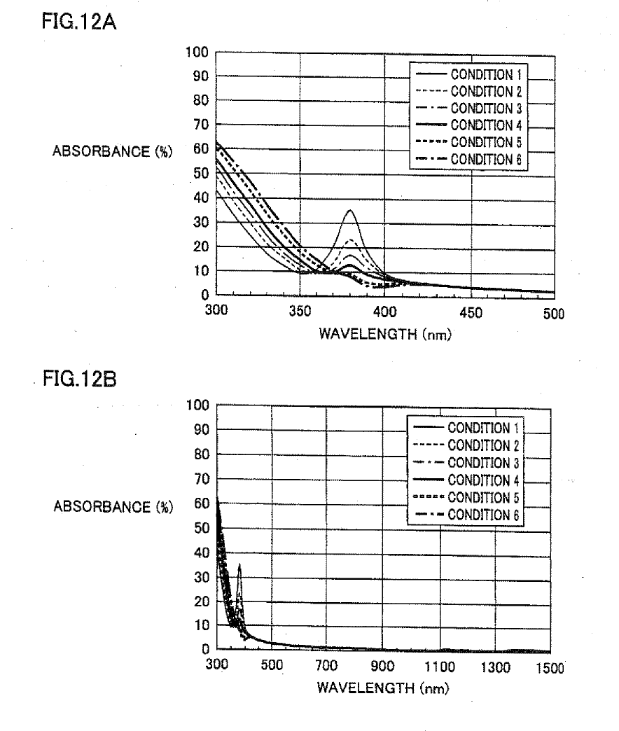

Then, in order to suppress the absorption of light around wavelength 380 nm of the polyethylene naphthalate film, a surface protective sheet for a solar cell was produced by forming an inorganic oxide film for the ultraviolet ray reflection on one surface of the polyethylene naphthalate film using a conventional technique that is used in an ultraviolet ray reflection filter made of glass. Here, a laminated body in where a plurality of layers of a silicon oxide film and a titanium oxide film are alternatively laminated was used as the inorganic oxide film, and 6 types of the film formation were performed in conditions 1 to 6 in which the thicknesses of the silicon oxide film and the titanium oxide film were changed in order to change the center wavelength of the reflecting light of the inorganic oxide film. Then, the light reflectance and transmittance were measured for each of the surface protective sheets for a solar cell in conditions 1 to 6. The measurement result of the reflectance of each of the surface protective sheets for a solar cell in conditions 1 to 6 is shown in FIGS. 10A and 10B, and the measurement result of the transmittance of each of the surface protective sheets for a solar cell in conditions 1 to 6 is shown in FIGS. 11A and 11B. Furthermore, the relationship of the absorbance and light wavelength of each of the surface protective sheets for a solar cell in conditions 1 to 6 calculated from FIGS. 10A, 10B, 11A and 11B is shown in FIGS. 12A and 12B.

As obvious from FIGS. 12A and 12B, by changing the center of the reflecting light wavelength in the inorganic oxide film of the surface protective sheet for a solar cell (the light wavelength at which the reflectance becomes the highest) from 350 am (condition 1) to 375 nm (condition 6), the absorbance of light having a wavelength of 380 nm over the entire of the surface protective sheet for a solar cell can be changed to 35% (condition 1), 24% (condition 2), 17% (condition 3), 13% (condition 4), 9% (condition 5), and 8% (condition 6).

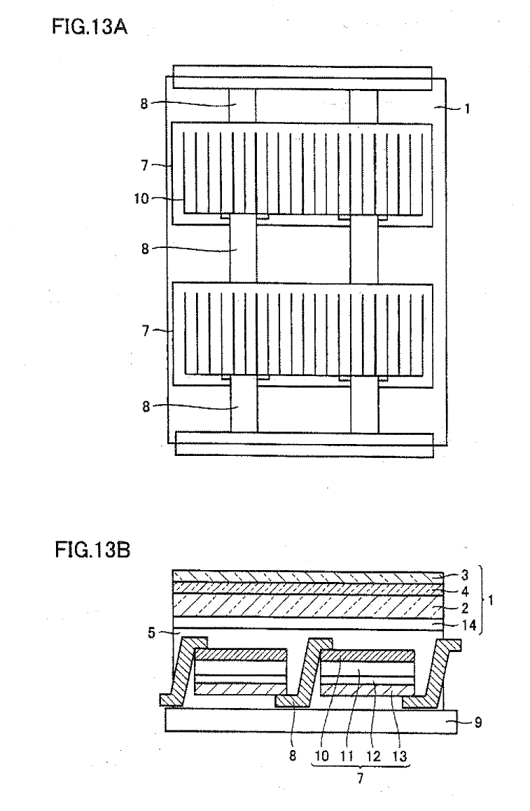

Next, a solar cell module having a constitution shown in FIGS. 13A and 13B was produced using the surface protective sheets for a solar cell in conditions 1 to 6 thus produced. In solar cell 7 that constitutes this solar cell module, a solar cell layer 11 was formed that was epitaxially grown on a GaAs substrate 12 in accordance with a MOCVD (Metal Organic Chemical Vapor Deposition) method for example.

Solar cell layer 11 has a constitution including an n-type GaAs contact layer that becomes the light receiving surface receiving sunlight, and two pn junctions of an n-type GaInP layer/p-type GaInP layer and an n-type GaAs layer/p-type GaAs layer. Further, a comb shaped n-type electrode 10 was formed on the surface of the n-type GaAs contact layer, and a p-type electrode 13 was formed on the rear surface of GaAs substrate 12.

Then, a solar cell string was formed by connecting n-type electrode 10 and p-type electrode 13 of one of two solar cells having the above constitution with interconnect 8, and this solar cell string was sealed in silicone resin 5 between a silicon oxide film 14 in the rear surface of surface protective sheet for a solar cell 1 and rear surface film 9.

Moreover, after removing the unnecessary portion of the n-type GaAs contact layer by etching by use of a conventionally known photolithography process and etching process, n-type electrode 10 was formed on the n-type GaAs contact layer by combining a conventionally known photolithography process, a vapor deposition process, a lift-off process, and a thermal treatment process, and its main component is silver (Ag).

Subsequently, a mask (not shown) was formed on the necessary portion of solar cell layer 11 with a normal photo masking process, and the unnecessary portion was removed by etching. Here, an ammonia-based etching liquid was used in the etching of the n-type GaAs layer and the p-type GaAs layer, and a hydrochloric acid based etching liquid was used in the etching of the n-type GaInP layer and the p-type GaInP layer.

Furthermore, a cut was created by half-dicing the periphery of GaAs substrate 12 in accordance with a normal dicing method, a prescribed shape was cut out in accordance with a normal break method, and then, p-type electrode 13 having silver (Ag) as a main component was formed on the rear surface of GaAs substrate 12. After that, a reflection preventing film (not shown) composed of a laminated body of a titanium oxide film and an aluminum oxide film was formed on the light receiving surface of solar cell layer 11 to complete solar cell 7.

Then, two solar cells 7 formed as described above were prepared, and a solar cell string was constituted where two solar cells 7 were connected in series by welding one end of interconnect 8 having silver (Ag) as a main component on n-type electrode 10 of one solar cell 7 and welding the other end of interconnect 8 on p-type electrode 13 of the other solar cell 7.

Next, the surface protective sheet for a solar cell 1 coated with silicone resin 5 and the solar cell string produced above were pasted together. First, silicon resin 5 was applied onto surface protective sheet for a solar cell 1.

Next, the above solar cell string was provided on a releasing paper so that the light receiving surface faces up, and surface protective sheet for a solar cell 1 coated with silicone resin 5 was adhered by laminating on top of the solar cell string.

In surface protective sheet for a solar cell 1, organic compound film 4 was formed directly on one surface of polyethylene naphthalate film 2, inorganic oxide film 3 where the condition is changed in the above conditions 1 to 6 was formed directly on the surface of organic compound film 4, and silicon oxide film 14 was formed on the other surface of polyethylene naphthalate film 2 at a thickness of 80 nm. That is, 6 types of surface protective sheets for a solar cell 1 each having a different constitution of inorganic oxide film 3 as in the above conditions 1 to 6 were formed as surface protective sheet for a solar cell 1.

Here, an organic compound film where a urethaneacrylate based resin having a thickness of 5 μm was formed by irradiating with ultraviolet rays was used as organic compound film 4. Further, inorganic oxide film 3 was made of a laminated body where a silicon oxide film and a titanium oxide film are alternatively laminated, and it has a constitution where the silicon oxide film is positioned at the outermost surface thereof. Moreover, the constitution of each inorganic oxide film 3 was formed independently with the condition of the above conditions 1 to 6, and it was designed to show the reflectance of FIGS. 10A and 10B and the transmittance of FIGS. 11A and 11B. Further, silicon oxide film 14 was formed on the other surface of polyethylene naphthalate film 2 at a thickness of 80 nm.

Subsequently, rear surface film 9 coated with silicone resin 5 was adhered by laminating on top of the solar cell string produced above. Thereafter, silicone resin 5 was cured by placing it in an oven of deforming treatment at 100° C. for 1 hour, and 6 types of the solar cell modules having the constitution shown in FIGS. 13A and 1313 were completed where each of 6 types of surface protective sheets for a solar cell 1 having each of inorganic oxide films 3 in conditions 1 to 6 was pasted.

Then, an ultraviolet ray irradiation test was performed on each of 6 types of the solar cell modules thus produced by performing the irradiation of pseudo sunlight using a xenon 5 kW optical source apparatus manufactured by USHIOSPAX Corporation. Here, the pseudo sunlight was adjusted to 200 times that of sunlight on the earth to accelerate the ultraviolet ray irradiation test.

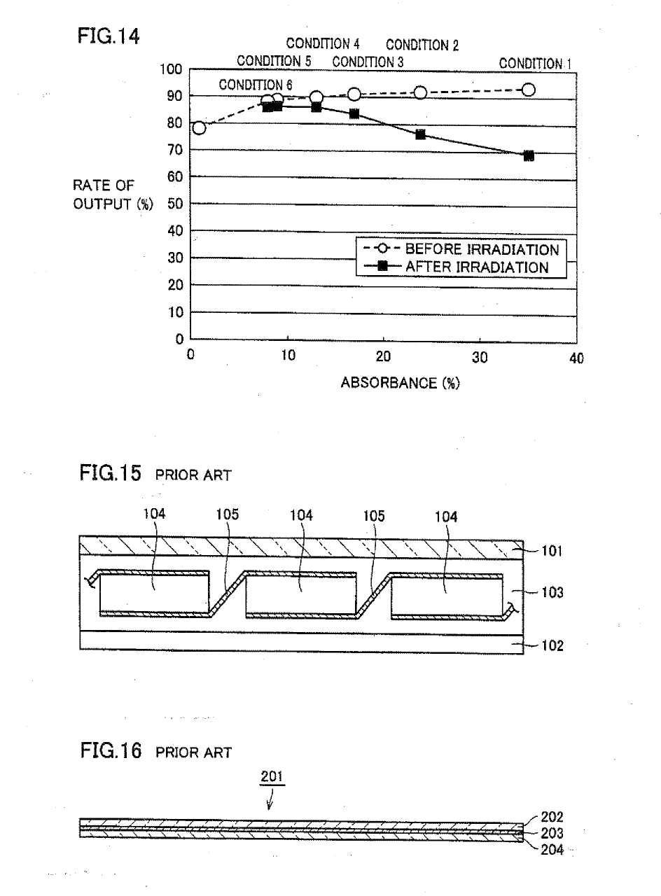

The relationship of the rate of output of the solar cell module when radiating pseudo sunlight equivalent to 3000 days onto each of the above 3 types of the solar modules and absorbance of light having a wavelength of 380 nm through the surface protective sheet for a solar cell is shown in FIG. 14. In FIG. 14, the x-axis shows the absorbance (%) of light having a wavelength of 380 nm through surface protective sheet for a solar cell 1, and the y-axis is the calculated rate (%) of output of the solar cell module after irradiation of pseudo sunlight equivalent to 3000 days as described above based on when the output of the solar cell string before pasting surface protective sheet for a solar cell 1 is made to be 100(%).

From the result shown in FIG. 14, if the output of the solar cell module after irradiation of pseudo sunlight equivalent to 3000 days necessarily becomes 80% or more of the output of the solar cell string before pasting surface protective sheet for a solar cell 1, it was confirmed that a solar cell module is necessarily produced using surface protective sheet for a solar cell 1 where the absorbance of light having a wavelength of 380 nm is 20% or less (surface protective sheet for a solar cell 1 containing inorganic oxide film 3 in conditions 3 to 6).

Further, according to the test separately performed, because the output of the solar cell module becomes less than 80% in case of producing the solar cell module using surface protective sheet for a solar cell 1 where the absorbance of light having a wavelength of 380 nm is less than 1%, it was confirmed that it is necessary to produce a solar cell module using surface protective sheet for a solar cell 1 where the absorbance of the light having a wavelength of 380 nm is 1% or more.

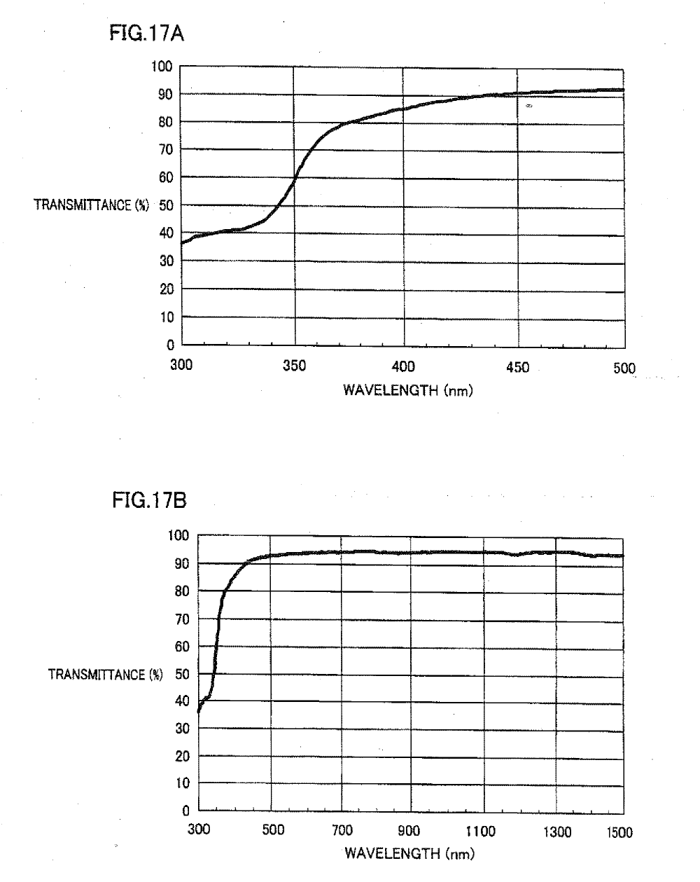

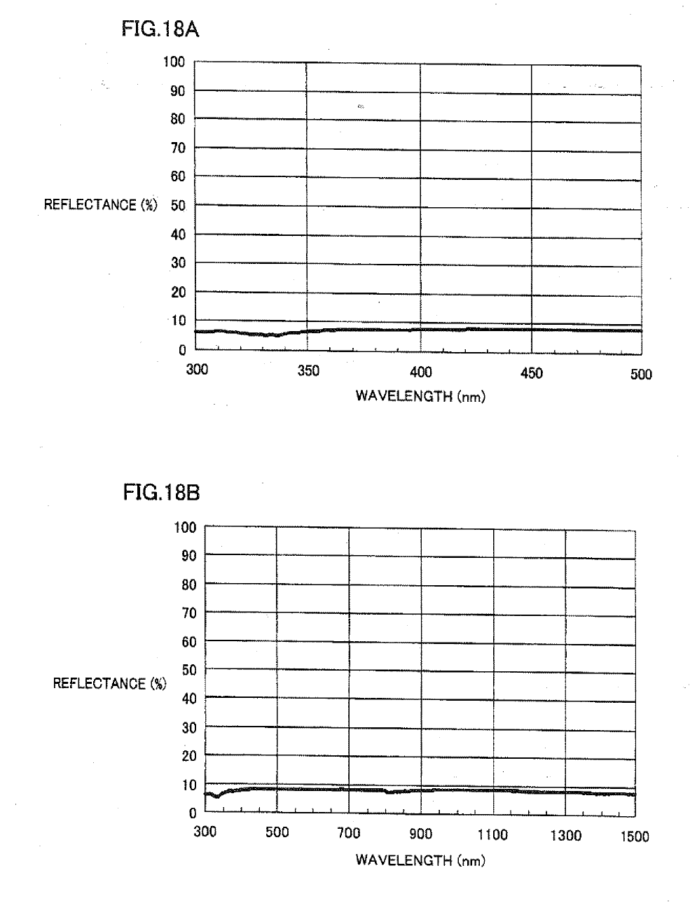

In order to clarify the mechanism of the polyamide-imide film turning yellow, the light transmittance and the reflectance of the polyamide-imide film were measured first. Here, an absolute reflectance measurement apparatus ARN-475 type manufactured by JASCO Corporation was used in the measurements of the transmittance and the reflectance of the polyamide-imide film. The light wavelength used in the measurement of the transmittance and the reflectance of the polyamide-imide film was made to be 300 nm to 1500 nm. The relationship of the light wavelength and transmittance of the polyamide-imide film is shown in FIGS. 17A and 17B, and the relationship of the light wavelength and reflectance of the polyamide-imide film is shown in FIGS. 18A and 18B.

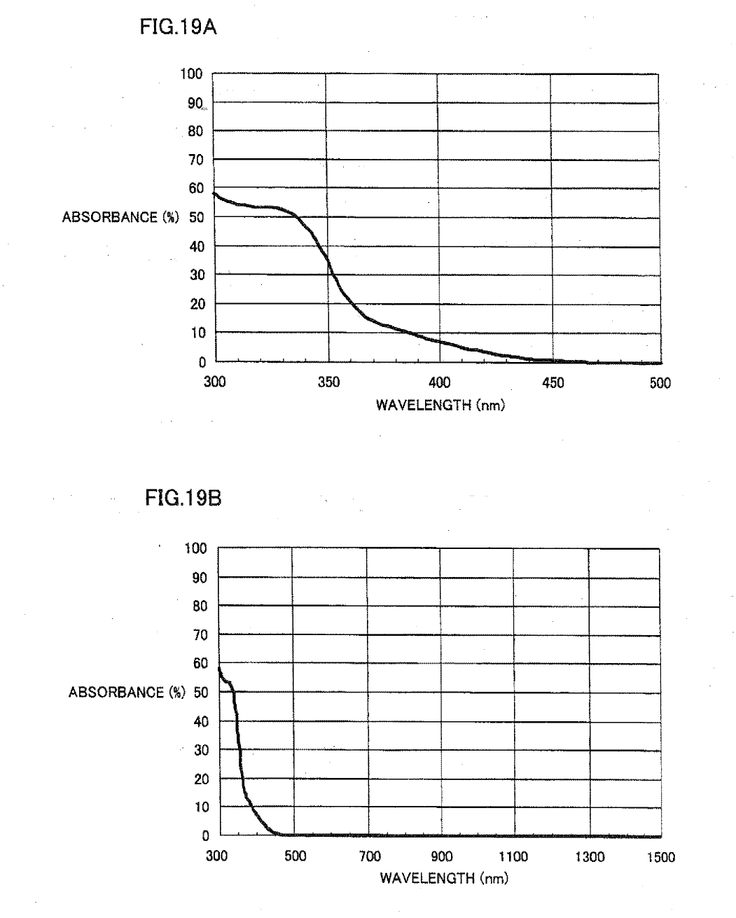

Based on the result of FIGS. 17A, 17B, 18A and 18B, the result of calculating the absorbance of the polyamide-imide film is shown in FIGS. 19A and 19B. Here, the absorbance is defined by the above formula (1).

As shown in FIGS. 19A and 19B, it was found that the absorbance of the polyamide-imide film becomes the highest around wavelength 325 nm.

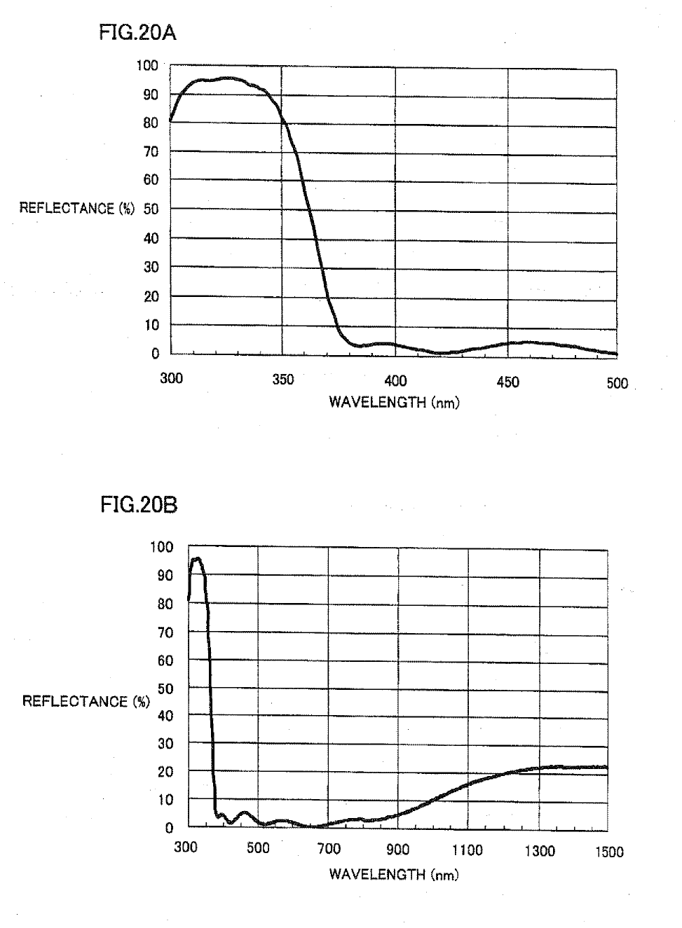

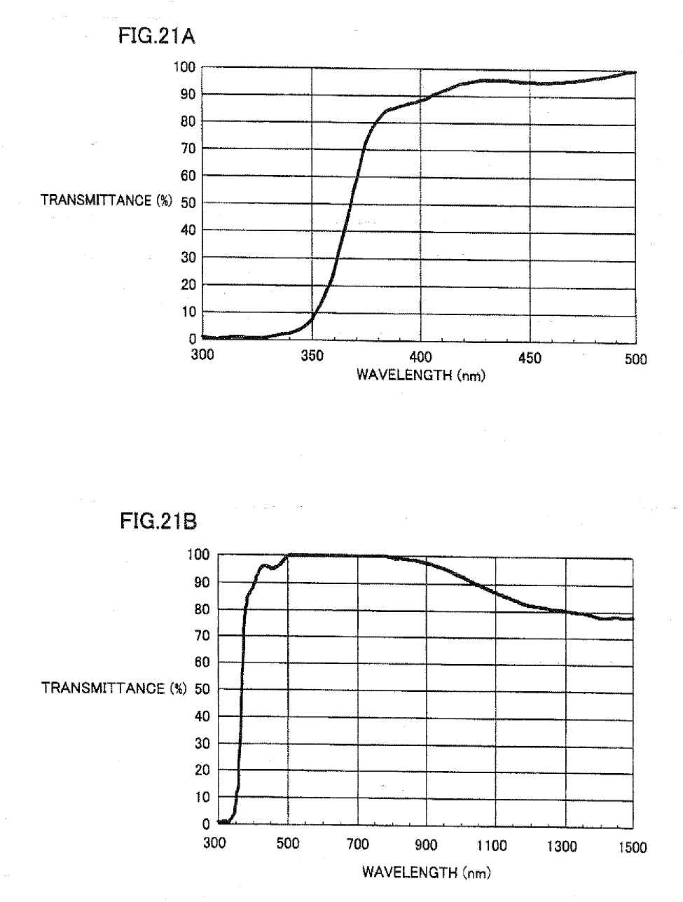

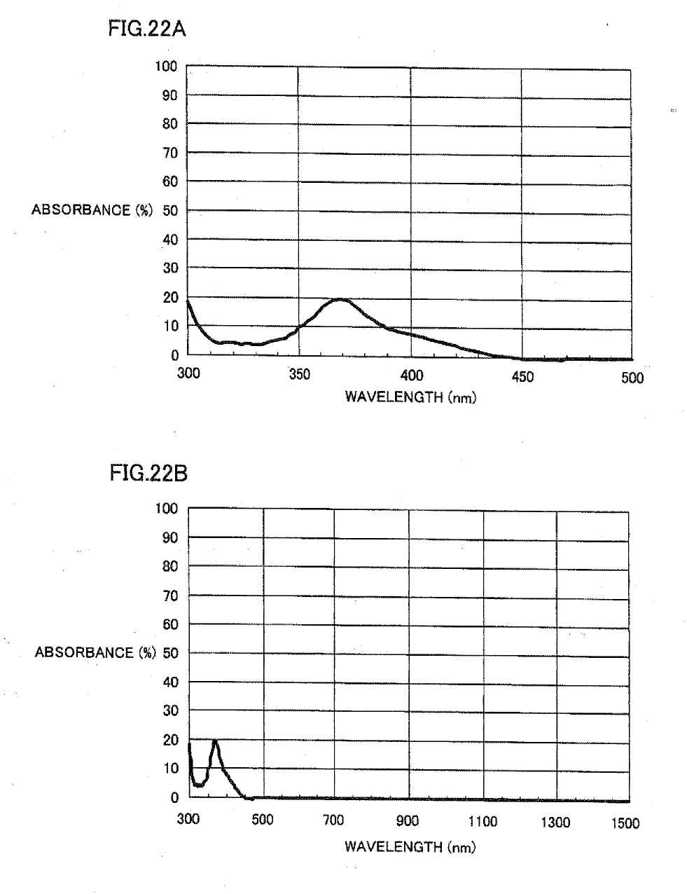

Then, in order to suppress the absorption of light around wavelength 325 nm of the polyamide-imide film, a surface protective sheet for a solar cell was produced by forming an inorganic oxide film for the ultraviolet ray reflection on one surface of the polyamide-imide film using a conventional technique that is used in an ultraviolet ray reflection filter made of glass. Here, a laminated body in where a plurality of layers of a silicon oxide film and a titanium oxide film are alternatively laminated was used as the inorganic oxide film, and 3 types of the film formation were performed in conditions 11 to 13 in which the thicknesses of the silicon oxide film and the titanium oxide film were changed in order to change the center wavelength of the reflecting light of the inorganic oxide film. Then, the light reflectance and transmittance were measured for the surface protective sheets for a solar cell in a typical condition 13. The measurement result of the reflectance of the surface protective sheet for a solar cell in condition 13 is shown in FIGS. 20A and 20B, and the measurement result of the transmittance of the surface protective sheet for a solar cell in condition 13 is shown in FIGS. 21A and 21B. Furthermore, the relationship of the absorbance and light wavelength of the surface protective sheet for a solar cell in condition 13 calculated from FIGS. 20A, 20B, 21A and 21B is shown in FIGS. 22A and 22B.

As in the polyethylene naphthalate film, by changing the center of the reflecting light wavelength in the inorganic oxide film of the surface protective sheet for a solar cell (the light wavelength at which the reflectance becomes the highest) to 375 nm (condition 11), 350 nm (condition 12) or 325 nm (condition 13), the absorbance of light having a wavelength of 325 nm over the entire of the surface protective sheet for a solar cell can be changed to 24% (condition 11), 15% (condition 12) and 4% (condition 13).

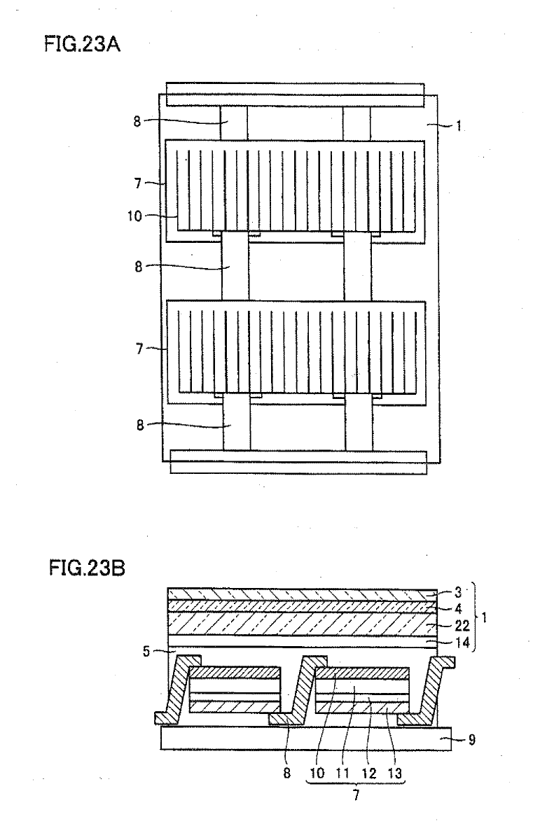

Next, a solar cell module having a constitution shown in FIGS. 23A and 23B was produced using the surface protective sheets for a solar cell in conditions 11 to 13 thus produced. In solar cell 7 that constitutes this solar cell module, a solar cell layer 11 was formed that was epitaxially grown on a GaAs substrate 12 in accordance with a MOCVD (Metal Organic Chemical Vapor Deposition) method for example.

Solar cell layer 11 has a constitution including an n-type GaAs contact layer that becomes the light receiving surface receiving sunlight, and two pn junctions of an n-type GaInP layer/p-type GaInP layer and an n-type GaAs layer/p-type GaAs layer. Further, a comb shaped n-type electrode 10 was formed on the surface of the n-type GaAs contact layer, and a p-type electrode 13 was formed on the rear surface of GaAs substrate 12.

Then, a solar cell string was formed by connecting n-type electrode 10 and p-type electrode 13 of one of two solar cells having the above constitution with interconnect 8, and this solar cell string was sealed in silicone resin 5 between a silicon oxide film 14 in the rear surface of surface protective sheet for a solar cell 1 and rear surface film 9.

Moreover, after removing the unnecessary portion of the n-type GaAs contact layer by etching by use of a conventionally known photolithography process and etching process, n-type electrode 10 was formed on the n-type GaAs contact layer by combining a conventionally known photolithography process, a vapor deposition process, a lift-off process, and a thermal treatment process, and its main component is silver (Ag).

Subsequently, a mask (not shown) was formed on the necessary portion of solar cell layer 11 with a normal photo masking process, and the unnecessary portion was removed by etching. Here, an ammonia-based etching liquid was used in the etching of the n-type GaAs layer and the p-type GaAs layer, and a hydrochloric acid based etching liquid was used in the etching of the n-type GaInP layer and the p-type GaInP layer.

Furthermore, a cut was created by half-dicing the periphery of GaAs substrate 12 in accordance with a normal dicing method, a prescribed shape was cut out in accordance with a normal break method, and then, p-type electrode 13 having silver (Ag) as a main component was formed on the rear surface of GaAs substrate 12. After that, a reflection preventing film (not shown) composed of a laminated body of a titanium oxide film and an aluminum oxide film was formed on the light receiving surface of solar cell layer 11 to complete solar cell 7.

Then, two solar cells 7 formed as described above were prepared, and a solar cell string was constituted where two solar cells 7 were connected in series by welding one end of interconnect 8 having silver (Ag) as a main component on n-type electrode 10 of one solar cell 7 and welding the other end of interconnect 8 on p-type electrode 13 of the other solar cell 7.

Next, the surface protective sheet for a solar cell 1 coated with silicone resin 5 and the solar cell string produced above were pasted together. First, silicon resin 5 was applied onto surface protective sheet for a solar cell 1.

Next, the above solar cell string was provided on a releasing paper so that the light receiving surface faces up, and surface protective sheet for a solar cell 1 coated with silicone resin 5 was adhered by laminating on top of the solar cell string.

In surface protective sheet for a solar cell 1, organic compound film 4 was formed directly on one surface of polyamide-imide film 22, inorganic oxide film 3 where the condition is changed in the above conditions 11 to 13 was formed directly on the surface of organic compound film 4, and silicon oxide film 14 was formed on the other surface of polyamide-imide film 22 at a thickness of 80 nm. That is, 3 types of surface protective sheets for a solar cell 1 each having a different constitution of inorganic oxide film 3 as in the above conditions 11 to 13 were formed as surface protective sheet for a solar cell 1.

Here, an organic compound film where a urethaneacrylate based resin having a thickness of 5 μm was formed by irradiating with ultraviolet rays was used as organic compound film 4. Further, inorganic oxide film 3 was made of a laminated body where a silicon oxide film and a titanium oxide film are alternatively laminated, and it has a constitution where the silicon oxide film is positioned at the outermost surface thereof. Moreover, the constitution of each inorganic oxide film 3 was formed independently with the condition of the above conditions 11 to 13. Further, silicon oxide film 14 was formed on the other surface of polyamide-imide film 22 at a thickness of 80 nm.

Subsequently, rear surface film 9 coated with silicone resin 5 was adhered by laminating on top of the solar cell string produced above. Thereafter, silicone resin 5 was cured by placing it in an oven of deforming treatment at 100° C. for 1 hour, and 3 types of the solar cell modules having the constitution shown in FIGS. 23A and 23B were completed where each of 3 types of surface protective sheets for a solar cell 1 having each of inorganic oxide films 3 in conditions 11 to 13 was pasted.

Then, an ultraviolet ray irradiation test was performed on each of 3 types of the solar cell modules thus produced by performing the irradiation of pseudo sunlight using a xenon 5 kW optical source apparatus manufactured by USHIOSPAX Corporation. Here, the pseudo sunlight was adjusted to 200 times that of sunlight on the earth to accelerate the ultraviolet ray irradiation test.

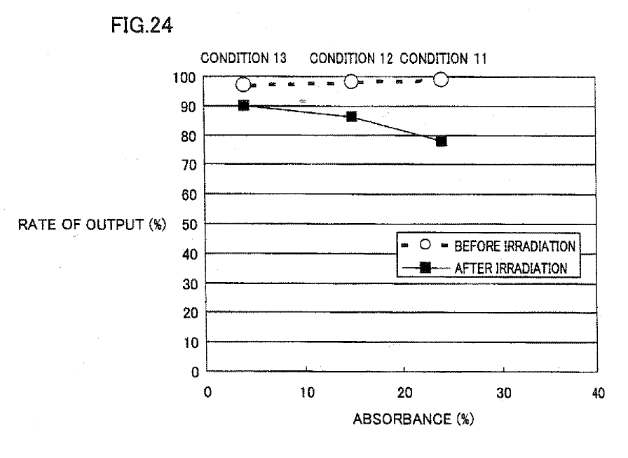

The relationship of the rate of output of the solar cell module when radiating pseudo sunlight equivalent to 3000 days onto each of the above 3 types of the solar modules and absorbance of light having a wavelength of 325 nm through the surface protective sheet for a solar cell is shown in FIG. 24. In FIG. 24, the x-axis shows the absorbance (%) of light having a wavelength of 325 nm through surface protective sheet for a solar cell 1 and the y-axis is the calculated rate (%) of output of the solar cell module after irradiation of pseudo sunlight equivalent to 3000 days as described above based on when the output of the solar cell string before pasting surface protective sheet for a solar cell 1 is made to be 100(%).

From the result shown in FIG. 24, if the output of the solar cell module after irradiation of pseudo sunlight equivalent to 3000 days necessarily becomes 80% or more of the output of the solar cell string before pasting surface protective sheet for a solar cell 1, it was confirmed that a solar cell module is necessarily produced using surface protective sheet for a solar cell 1 where the absorbance of light having a wavelength of 325 nm is 20% or less (surface protective sheet for a solar cell 1 containing inorganic oxide film 3 in conditions 12 and 13).

Further, according to the test separately performed, because the output of the solar cell module becomes less than 80% in case of producing the solar cell module using surface protective sheet for a solar cell 1 where the absorbance of light having a wavelength of 325 nm is less than 1%, it was confirmed that it is necessary to produce a solar cell module using surface protective sheet for a solar cell 1 where the absorbance of the light having a wavelength of 325 nm is 1% or more.

According to the present invention, a surface protective sheet for a solar cell capable of suppressing a decrease of output of a solar cell module during a long period of use, and a solar cell module using the same, can be provided.

The solar cell module using the surface protective sheet for a solar cell of the present invention can be preferably used in a space solar cell module (for artificial satellite) for example.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A surface protective sheet for a solar cell, comprising
a polyethylene naphthalate film and
an inorganic oxide film formed on one surface of said polyethylene naphthalate film, wherein
the absorbance of light having a wavelength of from 350 nm to 400 nm is from 1% to 20%.

2. The surface protective sheet for a solar cell according to claim 1, wherein said inorganic oxide film is a laminated body of a silicon oxide film and a titanium oxide film or a laminated body of a silicon oxide film and a tantalum oxide film.

3. The surface protective sheet for a solar cell according to claim 2, wherein said silicon oxide film is positioned on the outermost surface of said inorganic oxide film.

4. The surface protective sheet for a solar cell according to claim 1, wherein an organic compound film is formed between said polyethylene naphthalate film and said inorganic oxide film, and wherein
said organic compound film is formed by curing a radiation curable resin.

5. The surface protective sheet for a solar cell according to claim 1, wherein a silicon oxide film is formed on the surface of said polyethylene naphthalate film opposite to the side where said inorganic oxide film is provided.

6. A solar cell module, wherein said surface protective sheet for a solar cell and said solar cell are adhered to each other with a silicone resin interposed therebetween, while the surface of the surface protective sheet for a solar cell according to claim 1 opposite to the side where said inorganic oxide film is provided is a solar cell side.

7. A surface protective sheet for a solar cell, comprising
a polyethylene naphthalate film and
an inorganic oxide film formed on one surface of said polyethylene naphthalate film, wherein
the absorbance of light having a wavelength of 380 nm is from 1% to 20%.

8. The surface protective sheet for a solar cell according to claim 7, wherein said inorganic oxide film is a laminated body of a silicon oxide film and a titanium oxide film or a laminated body of a silicon oxide film and a tantalum oxide film.

9. The surface protective sheet for a solar cell according to claim B, wherein said silicon oxide film is positioned on the outermost surface of said inorganic oxide film.

10. The surface protective sheet for a solar cell according to claim 7 wherein an organic compound film is formed between said polyethylene naphthalate film and said inorganic oxide film, and wherein
said organic compound film is formed by curing a radiation curable resin.

11. The surface protective sheet for a solar cell according to claim 7, wherein a silicon oxide film is formed on the surface of said polyethylene naphthalate film opposite to the side where said inorganic oxide film is provided.

12. A solar cell module, wherein said surface protective sheet for a solar cell and said solar cell are adhered to each other with a silicone resin interposed therebetween, while the surface of the surface protective sheet for a solar cell according to claim 7 opposite to the side where said inorganic oxide film of the polyethylene naphthalate film is provided is a solar cell side.

13. A surface protective sheet for a solar cell, comprising
a polyamide-imide film and
an inorganic oxide film formed on one surface of said polyamide-imide film, wherein
the absorbance of light having a wavelength of from 300 nm to 350 nm is from 1% to 20%.

14. A surface protective sheet for a solar cell, comprising
a polyamide-imide film and
an inorganic oxide film formed on one surface of said polyamide-imide film, wherein
the absorbance of light having a wavelength of 325 nm is from 1% to 20%.
